(19) United States
(12) Patent Application Publication
(10) Pub. No.: US 2021/0057671 A1
(43) Pub. Date: Feb. 25, 2021

(54) ORGANIC ELECTROLUMINESCENT SUBSTRATE AND ORGANIC ELECTROLUMINESCENT DISPLAY PANEL

(71) Applicant: BOE Technology Group Co., Ltd., Beijing (CN)

(72) Inventors: Hao GAO, Beijing (CN); Xing FAN, Beijing (CN)

(73) Assignee: BOE Technology Group Co., Ltd.

(21) Appl. No.: 16/925,665

(22) Filed: Jul. 10, 2020

(30) Foreign Application Priority Data
Aug. 19, 2019 (CN) 201910762749.2

(51) Int. Cl. H01L 51/52; H01L 27/32

(52) U.S. Cl. CPC H01L 51/5218; H01L 27/3283; H01L 27/3246; H01L 51/5271

(57) ABSTRACT

The present disclosure discloses an organic electroluminescent substrate and an organic electroluminescent display panel. The organic electroluminescent substrate includes a planarization layer, an insulating layer, a first electrode, a pixel definition layer, an organic light-emitting layer and a second electrode, wherein a surface of the pixel definition layer away from the planarization layer is flush with a surface of the insulating layer away from the planarization layer.

### CROSS-REFERENCE TO RELATED APPLICATION

This application claims priority to Chinese Patent Application No. 201910762749.2, filed Aug. 19, 2019, the content of which is incorporated by reference in its entirety.

### FIELD

The present disclosure relates to the field of display technology, and in particular relates to an organic electroluminescent substrate and an organic electroluminescent display panel.

### SUMMARY

Embodiments of the present disclosure provide an organic electroluminescent substrate and an organic electroluminescent display panel.

In a first aspect, an embodiment of the present disclosure provides an organic electroluminescent substrate.

This organic electroluminescent substrate includes:
a planarization layer;
an insulating layer on the planarization layer; wherein the insulating layer includes a plurality of openings distributed in an array;
a first electrode formed of a metal material; wherein the first electrode covers the bottoms of the plurality of openings, side faces of the plurality of openings, and a surface of the insulating layer away from the planarization layer, and portions of the first electrode at the bottoms of the plurality of openings and portions of the first electrode at the side faces of the plurality of openings cooperate to form a reflective cup structure;
a pixel definition layer in the plurality of openings, configured to define a pixel cell area; wherein a surface of the pixel definition layer away from the planarization layer is flush with a surface of the insulating layer away from the planarization layer;
an organic light-emitting layer on a side of the first electrode away from the planarization layer and at least covering the portions of the first electrode at the bottoms of the plurality of openings; wherein the pixel definition layer is between the organic light-emitting layer and the first electrode; and
a second electrode on a side of the organic light-emitting layer away from the planarization layer.

In the embodiment, an orthographic projection, on the planarization layer, of the second electrode overlaps with an orthographic projection, on the planarization layer, of a part of the organic light-emitting layer covering the portions of the first electrode at the bottoms of the plurality of openings.

In the embodiment, an orthographic projection, on the planarization layer, of the organic light-emitting layer at least covers an orthographic projection, on the planarization layer, of the portions of the first electrode at the bottoms of the plurality of openings.

In the embodiment, the orthographic projection, on the planarization layer, of the organic light-emitting layer has an overlapping area with an orthographic projection, on the planarization layer, of a portion of the first electrode covering a side of the insulating layer away from the planarization layer.

In the embodiment, the orthographic projection, on the planarization layer, of the organic light-emitting layer does not overlap with an orthographic projection, on the planarization layer, of a portion of the first electrode covering a side of the insulating layer away from the planarization layer.

In the embodiment, a partial area of the portions of the first electrode at the bottoms of the plurality of openings comprises a fracture area, and an orthographic projection, on the planarization layer, of the partial area does not overlap with an orthographic projection, on the planarization layer, of the second electrode.

In the embodiment, a heat-shrinkable rubber is added into an area of the planarization layer, and the fracture area is formed by performing thermal plasticization on the heat-shrinkable rubber, wherein an orthographic projection, on the planarization layer, of the area of the planarization layer overlaps with an orthographic projection, on the planarization layer, of the pixel definition layer.

In the embodiment, the heat-shrinkable rubber is a polyester material.

In the embodiment, the first electrode is an anode, and the second electrode is a cathode.

In a second aspect, an embodiment of the present disclosure further provides an organic electroluminescent display panel, including any organic electroluminescent substrate provided in the above embodiment.

### BRIEF DESCRIPTION OF THE DRAWINGS

FIG. 1 is a schematic structural diagram of an organic electroluminescent substrate in the related art.

FIG. 2 is a schematic structural diagram of an organic electroluminescent substrate provided by embodiments of the present disclosure.

FIG. 3 is a schematic plan view of an organic electroluminescent substrate provided by the embodiments of the present disclosure.

FIGS. 4A, 4B, and 4C are schematic diagrams of a manufacturing process of an organic electroluminescent layer provided by the embodiments of the present disclosure.

FIGS. 5A and 5B are schematic diagrams of a manufacturing process of a first electrode provided by the embodiments of the present disclosure.

### DETAILED DESCRIPTION OF THE EMBODIMENTS

The technical solutions in the embodiments of the present disclosure will be described below clearly and completely in conjunction with the accompanying drawings in the embodiments of the present disclosure. Obviously, the described embodiments are only a part of the embodiments of the present disclosure, and not all the embodiments. All other embodiments obtained by those of ordinary skill in the art without creative work, based on the embodiments in the present disclosure, fall into the protection scope of the present disclosure.

The following are the reference signs in the drawing of this application.
01—planarization layer; 02—raised layer; 03—first electrode; 04—pixel definition layer; 05—organic light-emitting layer; 06—second electrode;
1—planarization layer; 2—insulating layer; 21—opening; 3—first electrode; 4—pixel definition layer; 5—organic light-emitting layer; 6—second electrode; 7—negative photoresist layer; 8—heat-shrinkable rubber.

In the related art, as shown in FIG. 1, which illustrates a conventional structure of a reflective cup of an organic electroluminescent substrate, the organic electroluminescent substrate includes a planarization layer 01, an insulating layer 02, an anode 03, a pixel definition layer 04, an organic light-emitting layer 05 and a cathode 06. In the reflective cup structure, the insulating layer 02 is configured with a raised structure so that the anode forms a reflective layer. In this way, transversely propagated energy such as waveguide energy can be effectively used to couple to the outside of a device, and the external coupling efficiency of the device is improved. However, when the waveguide energy is propagated into the pixel definition layer, part of light is propagated along the pixel definition layer on a top part of the insulating layer, and this loss affects the extraction efficiency of the reflective cup.

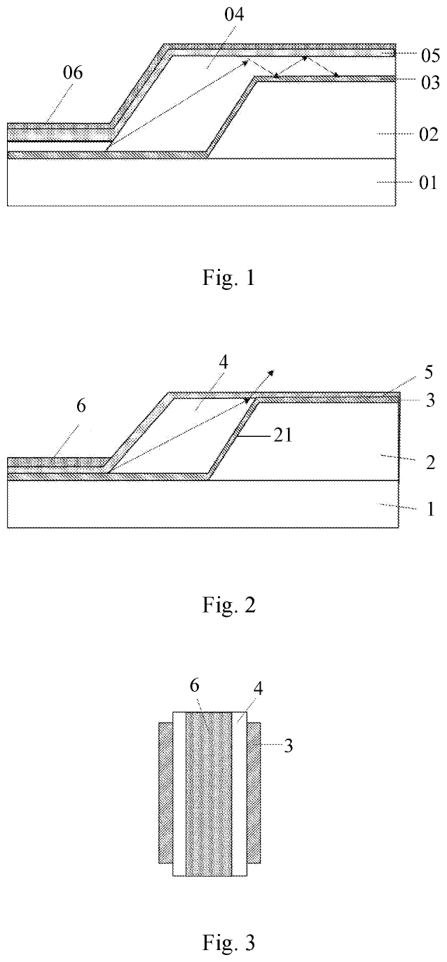

Therefore, referring to FIGS. 2 and 3, the present disclosure provides an organic electroluminescent substrate, including:
a planarization layer 1;
an insulating layer 2 on the planarization layer 1; wherein the insulating layer 2 includes a plurality of openings 21 distributed in an array;
a first electrode 3 formed of a metal material; wherein the first electrode 3 covers the bottoms of the plurality of openings 21, side faces of the plurality of openings 21, and a surface of the insulating layer 2 away from the planarization layer 1, and portions of the first electrode 3 located at the bottoms of the plurality of openings 21 and portions of the first electrode 3 at the side faces of the plurality of openings 21 cooperate to form a reflective cup structure;
a pixel definition layer 4 in the plurality of openings 21, configured for define a pixel cell area, wherein a surface of the pixel definition layer 4 away from the planarization layer 1 is flush with a surface of the insulating layer 2 away from the planarization layer 1;
an organic light-emitting layer 5 on a side of the first electrode 3 away from the planarization layer 1 and at least covering the portions of the first electrode 3 at the bottoms of the plurality of openings 21, wherein the pixel definition layer 4 is between the organic light-emitting layer 5 and the first electrode 3; and
a second electrode 6 on a side of the organic light-emitting layer 5 away from the planarization layer 1.

The organic electroluminescent substrate provided by the above embodiment of the present disclosure includes the planarization layer 1, the insulating layer 2, the first electrode 3, the pixel definition layer 4, the organic light-emitting layer 5 and the second electrode 6. The insulating layer 2 is located on the planarization layer 1 and has a plurality of openings 21 distributed in an array. The first electrode 3 covers the bottoms of the plurality of openings 21, the side surfaces of the plurality of opening 21, and the surface of the insulating layer 2 away from the planarization layer 1. And the portions of the first electrode 3 at the bottoms of the plurality of openings 21 and the portions of the first electrode 3 at the side surfaces of the plurality of openings 21 cooperate to form a reflective cup structure. The pixel definition layer 4 is formed in the plurality of openings 21. The reflective cup structure can use transversely propagated energy such as waveguide energy to couple to the outside of a device and improve the external coupling efficiency of the device. As the surface of the pixel definition layer 4 away from the planarization layer 1 is flush with the surface of the insulating layer 2 away from the planarization layer 1, compared with the related art, a pixel definition layer on a side of the insulating layer 2 away from the planarization layer 1 is removed, thereby avoiding the loss caused by transverse propagation of light along the pixel definition layer 4, and improving the extraction efficiency of the reflective cup structure.

It should be noted that the external coupling efficiency (EQE) is obtained by dividing the quantity of light detected outside the device by the total quantity of light emitted by a luminescent material. The extraction efficiency refers to a conversion rate by which the reflection cup structure converts the waveguide-mode energy into externally coupled light.

In the above-mentioned organic electroluminescent substrate, in some embodiments, an orthographic projection of the second electrode 6 on the planarization layer 1 may substantially overlap with an orthographic projection, on the planarization layer 1, of a part of the organic light-emitting layer 5 covering the portions of the first electrode 3 at the bottoms of the plurality of openings 21. That is, the deposition range of the second electrode 6 is within the pixel cell area, thus avoiding problems such as a short circuit due to contact between the first electrode 3 and the second electrode 6, on the side of the insulating layer 2 away from the planarization layer 1. In some embodiments, in the preparation of the above-mentioned organic electroluminescent substrate, a second electrode material may be evaporated by using a fine metal mask.

In the above-mentioned organic electroluminescent substrate, in some embodiments, an orthographic projection of the organic light-emitting layer 5 on the planarization layer 1 at least covers an orthographic projection, on the planarization layer 1, of the portions of the first electrode 3 located at the bottoms of the plurality of openings 21.

In some embodiments, the orthographic projection of the organic light-emitting layer 5 on the planarization layer 1 may have an overlapping area with an orthographic projection, on the planarization layer 1, of a portion of the first electrode 3 covering a side of the insulating layer 2 away from the planarization layer las shown in FIG. 2.

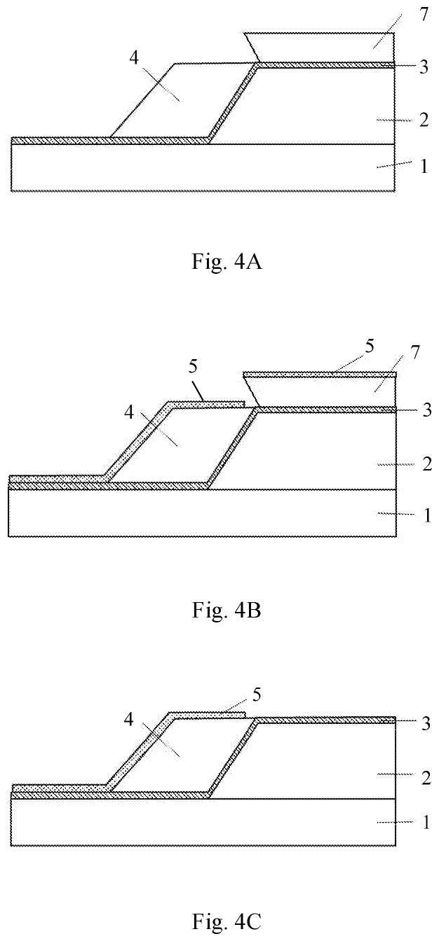

In some embodiments, the orthographic projection of the organic light-emitting layer 5 on the planarization layer 1 may not overlap with the orthographic projection, on the planarization layer 1, of the portion of the first electrode 3 covering the side of the insulating layer 2 away from the planarization layer 1, as shown in FIG. 4C. The phenomenon of light emission or a short circuit can be avoided by removing an organic light-emitting layer 5 and an second electrode 6 deposited on the side of the insulating layer 2 away from the planarization layer 1. FIGS. 4A-4C shows a specific manufacturing process for forming the organic light-emitting layer 5. As shown in FIG. 4A, after forming the pixel definition layer 4, an inverted-trapezoidal negative photoresist layer 7 is formed on the side of the first electrode 3 away from the insulating layer 2, and an orthographic projection, on the planarization layer 1, of a surface of the inverted-trapezoidal negative photoresist layer 7 away from the first electrode 3 covers an orthographic projection, on the planarization layer 1, of the side of the first electrode 3 away from the insulating layer 2. As shown in FIG. 4B, an organic light-emitting layer 5 is prepared by evaporation. As shown in FIG. 4C, the inverted-trapezoidal negative photoresist layer 7 is removed to obtain an organic light-emitting layer 5, wherein the orthographic projection of the obtained organic light-emitting layer 5 on the planarization layer 1 does not overlap with the orthographic projection, on the planarization layer 1, of the portion of the first electrode 3 covering the side of the insulating layer 2 away from the planarization layer 1. in some embodiments, the material of the negative photoresist layer 7 may be a polyimide photoresist.

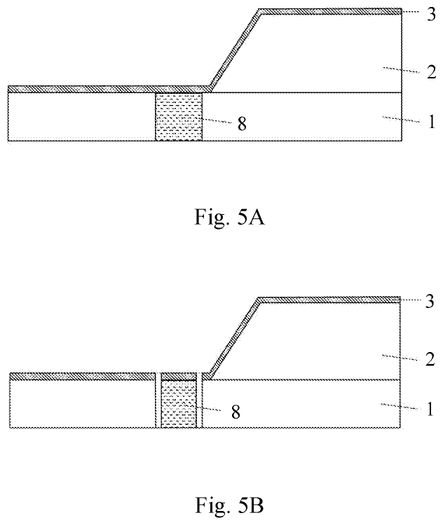

In the above-mentioned organic electroluminescent substrate, in some embodiments, an area of a portion of the first electrode 3 covering the bottom of the opening 21 that is not opposite to a portion of the second electrode 6 covering the bottom of the opening 21 has a fracture area, as shown in FIG. 5B. That is, a disconnection design is performed on the first electrode 3 so that the portion of the first electrode 3 deposited on the insulating layer 2 does not conductive, and the organic layer and the cathode can be normally deposited on the side of the insulating layer 2 away from the planarization layer 1 without the phenomenon of light emission or a short circuit.

In the above-mentioned organic electroluminescent substrate, in some embodiments, a heat-shrinkable rubber 8 is added into an area of the planarization layer 1 opposite to the pixel definition layer 4, and the fracture area is formed by performing thermal plasticization on the heat-shrinkable rubber 8. As shown in FIG. 5A, a heat-shrinkable rubber 8 is added into an area of the planarization layer 1 opposite to the pixel definition layer 4; and as shown in FIG. 5B, after forming a layer of first electrode 3 on the planarization layer 1 and on the insulating layer 2, the heat-shrinkable rubber 8 is subjected to thermal plasticization, so that the heat-shrinkable rubber 8 shrinks and fractures are generated in the first electrode 3. In some embodiments, the heat-shrinkable rubber 8 may be a polyester material.

In the above-mentioned organic electroluminescent substrate, in some embodiments, the first electrode 3 is an anode, and the second electrode 6 is a cathode.

The present disclosure further provides an organic electroluminescent display panel, including any organic electroluminescent substrate provided in the above technical solution.

Evidently those skilled in the art can make various modifications and variations to the embodiments of the present disclosure without departing from the spirit and scope of the present disclosure. Thus, the present disclosure is also intended to encompass these changes and modifications if such changes and modifications of the present disclosure are within the scope of the claims of the present disclosure and equivalents thereof.

What is claimed is:

1. An organic electroluminescent substrate, comprising:
a planarization layer;
an insulating layer on the planarization layer; wherein the insulating layer comprises a plurality of openings distributed in an array;
a first electrode formed of a metal material; wherein the first electrode covers the bottoms of the plurality of openings, side faces of the plurality of openings, and a surface of the insulating layer away from the planarization layer, and portions of the first electrode at the bottoms of the plurality of openings and portions of the first electrode at the side faces of the plurality of openings cooperate to form a reflective cup structure;
a pixel definition layer in the plurality of openings, configured to define a pixel cell area; wherein a surface of the pixel definition layer away from the planarization layer is flush with a surface of the insulating layer away from the planarization layer;
an organic light-emitting layer on a side of the first electrode away from the planarization layer and at least covering the portions of the first electrode at the bottoms of the plurality of openings; wherein the pixel definition layer is between the organic light-emitting layer and the first electrode; and
a second electrode on a side of the organic light-emitting layer away from the planarization layer.

2. The organic electroluminescent substrate according to claim 1, wherein an orthographic projection, on the planarization layer, of the second electrode overlaps with an orthographic projection, on the planarization layer, of a part of the organic light-emitting layer covering the portions of the first electrode at the bottoms of the plurality of openings.

3. The organic electroluminescent substrate according to claim 1, wherein an orthographic projection, on the planarization layer, of the organic light-emitting layer at least covers an orthographic projection, on the planarization layer, of the portions of the first electrode at the bottoms of the plurality of openings.

4. The organic electroluminescent substrate according to claim 3, wherein the orthographic projection, on the planarization layer, of the organic light-emitting layer has an overlapping area with an orthographic projection, on the planarization layer, of a portion of the first electrode covering a side of the insulating layer away from the planarization layer.

5. The organic electroluminescent substrate according to claim 3, wherein the orthographic projection, on the planarization layer, of the organic light-emitting layer does not overlap with an orthographic projection, on the planarization layer, of a portion of the first electrode covering a side of the insulating layer away from the planarization layer.

6. The organic electroluminescent substrate according to claim 2, wherein a partial area of the portions of the first electrode at the bottoms of the plurality of openings comprises a fracture area, and an orthographic projection, on the planarization layer, of the partial area does not overlap with an orthographic projection, on the planarization layer, of the second electrode.

7. The organic electroluminescent substrate according to claim 6, wherein a heat-shrinkable rubber is added into an area of the planarization layer, and the fracture area is formed by performing thermal plasticization on the heat-shrinkable rubber, wherein an orthographic projection, on the planarization layer, of the area of the planarization layer overlaps with an orthographic projection, on the planarization layer, of the pixel definition layer.

8. The organic electroluminescent substrate according to claim 7, wherein the heat-shrinkable rubber is a polyester material.

9. The organic electroluminescent substrate according to any one of claims 1, wherein the first electrode is an anode and the second electrode is a cathode.

10. An organic electroluminescent display panel, comprising an organic electroluminescent substrate, wherein the organic electroluminescent substrate comprises:
a planarization layer;
an insulating layer on the planarization layer; wherein the insulating layer comprises a plurality of openings distributed in an array;
a first electrode formed of a metal material; wherein the first electrode covers the bottoms of the plurality of openings, side faces of the plurality of openings, and a surface of the insulating layer away from the planarization layer, and portions of the first electrode at the bottoms of the plurality of openings and portions of the first electrode at the side faces of the plurality of openings cooperate to form a reflective cup structure;
a pixel definition layer in the plurality of openings, configured to define a pixel cell area; wherein a surface of the pixel definition layer away from the planarization layer is flush with a surface of the insulating layer away from the planarization layer;
an organic light-emitting layer on a side of the first electrode away from the planarization layer and at least covering the portions of the first electrode at the bottoms of the plurality of openings; wherein the pixel definition layer is between the organic light-emitting layer and the first electrode; and
a second electrode on a side of the organic light-emitting layer away from the planarization layer.

11. The organic electroluminescent display panel according to claim 10, wherein an orthographic projection, on the planarization layer, of the second electrode overlaps with an orthographic projection, on the planarization layer, of a part of the organic light-emitting layer covering the portions of the first electrode at the bottoms of the plurality of openings.

12. The organic electroluminescent display panel according to claim 10, wherein an orthographic projection, on the planarization layer, of the organic light-emitting layer at least covers an orthographic projection, on the planarization layer, of the portions of the first electrode at the bottoms of the plurality of openings.

13. The organic electroluminescent display panel according to claim 12, wherein the orthographic projection, on the planarization layer, of the organic light-emitting layer has an overlapping area with an orthographic projection, on the planarization layer, of a portion of the first electrode covering a side of the insulating layer away from the planarization layer.

14. The organic electroluminescent display panel according to claim 12, wherein the orthographic projection, on the planarization layer, of the organic light-emitting layer does not overlap with an orthographic projection, on the planarization layer, of a portion of the first electrode covering a side of the insulating layer away from the planarization layer.

15. The organic electroluminescent display panel according to claim 11, wherein an area of a portion of the first electrode covering a bottom of a respective one of the openings that is not opposite to a portion of the second electrode covering a bottom of a respective one of the openings comprises a fracture area.

16. The organic electroluminescent display panel according to claim 15, wherein a heat-shrinkable rubber is added into an area of the planarization layer, and the fracture area is formed by performing thermal plasticization on the heat-shrinkable rubber, wherein an orthographic projection, on the planarization layer, of the area of the planarization layer overlaps with an orthographic projection, on the planarization layer, of the pixel definition layer.

17. The organic electroluminescent display panel according to claim 16, wherein the heat-shrinkable rubber is a polyester material.

18. The organic electroluminescent display panel according to claim 10, wherein the first electrode is an anode and the second electrode is a cathode.
